(19) United States
(12) Patent Application Publication
(10) Pub. No.: US 2016/0225915 A1
(43) Pub. Date: Aug. 4, 2016

(54) Metal oxynitride transistor devices

(71) Applicants: Cindy X. Qiu, Brossard (CA); Andy Shih, Brossard (CA); Yi-Chi Shih, Los Angeles, CA (US); Ishiang Shih, Brossard (CA); Chunong Qiu, Brossard (CA); Julia Qiu, Brossard (CA)

(72) Inventors: Cindy X. Qiu, Brossard (CA); Andy Shih, Brossard (CA); Yi-Chi Shih, Los Angeles, CA (US); Ishiang Shih, Brossard (CA); Chunong Qiu, Brossard (CA); Julia Qiu, Brossard (CA)

(21) Appl. No.: 14/544,652

(22) Filed: Jan. 30, 2015

(51) Int. Cl. H01L 29/786; H01L 29/49; H01L 29/423; H01L 29/24

(52) U.S. Cl. CPC H01L 29/78696; H01L 29/24; H01L 29/7869; H01L 29/4958; H01L 29/42364; H01L 29/42372; H01L 29/78603; H01L 29/78609

(57) ABSTRACT

Transistors with a first metal oxynitride channel layer and a second metal oxynitride barrier layer are provided. The first metal oxynitride channel layer is lightly doped or without intentional doping to achieve high carrier mobility. Impurity atoms are introduced into the second metal oxynitride barrier layer and the donated carriers migrate or drift into the first metal oxynitride channel layer to effect high mobility conduction between source and drain.

### FIELD OF INVENTION

This invention relates to transistor having a metal oxynitride barrier layer and a metal oxynitride channel layer for forming a circuit for power switching or for microwave amplification.

### BACKGROUND OF THE INVENTION

In semiconductor devices, the electronic and optoelectronic performance is determined by several parameters such as band gap, electron or hole carrier density, mobility and lifetime of the electrons or holes. For unipolar devices like field effect transistor (FET) or thin film transistor (TFT), electron carrier mobility μₙ at room temperature is a key parameter which affect the transconductance and ON state channel resistance. The performance improves as the carrier mobility is increased. For monocrystalline semiconductors Si and GaAs, the mobility is mainly limited by scattering with acoustic phonons (μ₁αT^{-3/2}) and scattering with ionized impurity (μ₁α T^{3/2}) and the combined mobility is μ=1/μ₁+1/μ₁ (S. M. Sze, Physics in Semiconductor Devices, John Wiley and Sons, 1981). For operation in a room environment near room temperatures, the carrier mobility in a semiconductor decreases with the increase in ionized impurity density. In electronic devices with an active channel layer involving semiconductor other than Si and GaAs and such as GaN, InN, InGaN, In₂O₃, InN and InON, thin films of metal nitride, metal oxide and metal oxynitride are deposited on a substrate to form an active channel layer for high electron mobility transistors (HEMT) or thin film transistors (TFT). These metal nitride, metal oxide and metal oxynitride thin films are deposited by methods including molecular beam epitaxy (MBE), metal organic chemical vapour deposition (MOCVD), reactive sputtering and reactive evaporation, all performed in a reduced atmosphere or a vacuum environment. Quality of the thin films deposited by MBE or MOCVD is often superior than that of the thin films prepared by reactive evaporation or reactive sputtering. For the thin films deposited by the reactive evaporation or reactive sputtering, the quality is often insufficient and the charge carrier mobility is often lower than intrinsic mobility of these metal nitride, metal oxide and metal oxynitride materials. Thus, it is desired to develop improved manufacturing procedure to provide thin films with improved carrier mobility and to provide new device structures with improved performance to meet the requirements of advanced applications.

### SUMMARY OF THE INVENTION

One objective of the invention is to provide an metal oxynitride transistor device having a first metal oxynitride channel layer and a second metal oxynitride barrier layer where doping impurity atoms are introduced in the second metal oxynitride barrier layer so that donated electrons drift to the first metal oxynitride channel layer to obtain high charge carrier mobility.

One other objective of the invention is to provide an metal oxynitride transistor device having a first metal oxynitride channel layer and a second metal oxynitride barrier layer and with a buffer layer introduced between the substrate and the first metal oxynitride channel layer to reduce unwanted defects.

Another objective of the invention is to provide an metal oxynitride transistor device having a first metal oxynitride channel layer, a second metal oxynitride barrier layer, a buffer layer and with a carrier blocking layer introduced between the buffer layer and the first metal oxynitride channel layer to confine free charge carriers in the first metal oxynitride channel layer to achieve high charge carrier mobility.

Yet another objective of the invention is to provide an metal oxynitride transistor device having a first metal oxynitride channel layer and a second metal oxynitride barrier layer and with a spacer layer introduced between the first metal oxynitride channel layer and the second metal oxynitride barrier layer to reduce further any unwanted coulomb interactions of the free electrons in the first metal oxynitride channel layer and to increase the charge carrier mobility.

Still another objective of the invention is to provide an metal oxynitride transistor device having a first metal oxynitride channel layer, a second metal oxynitride barrier layer, a buffer layer and with a impurity doping layer introduced between the first metal oxynitride channel layer and the second metal oxynitride barrier layer so that no intentional impurity doping is needed in the second metal oxynitride barrier layer and gate breakdown voltage is improved.

### BRIEF DESCRIPTION OF THE SEVERAL VIEWS OF THE DRAWINGS

FIG. 1 A schematic cross sectional diagram of a metal oxynitride transistor (100) having a first metal oxynitride channel layer (110) and a second metal oxynitride barrier layer (120) on a first substrate (105) with a source contact layer (130) and a drain contact layer (140).

FIG. 2a An energy band diagram of the metal oxynitride transistor (100) taken along line A-B in FIG. 1, showing free electrons (170E) in the first metal oxynitride channel layer (110) donated by impurity atoms (170D) in the second metal oxynitride barrier layer (120), due to the presence of energy step (160) resulting from a difference between E_{CB1} and E_{CB2}, where E_{g1}<E_{g2}.

FIG. 2b An energy band diagram of metal oxynitride transistor (100) taken along line A-B in FIG. 1, showing free electrons (170E′) in the first metal oxynitride channel layer (110) donated by impurity atoms (170D′) in the second metal oxynitride barrier layer (120), due to the presence of energy step (160′) resulting from difference between E_{CB1}′ and E_{CB2}′, where E_{g1}′≈E_{g2}′.

FIG. 3 A schematic cross sectional view of the channel region of a metal oxynitride transistor (300) with a first metal oxynitride channel layer (110), a second metal oxynitride barrier layer (120), a first gate layer (150) and a gate insulating layer (310), forming an MIS gate structure to reduce leakage currents from the first gate layer.

FIG. 4a A schematic cross sectional diagram of the channel region of a metal oxynitride transistor (400) having a first metal oxynitride channel layer (110) and a second metal oxynitride barrier layer (120). A gate structure with a first gate layer (150) and a second gate layer (410) is adopted to reduce unwanted gate series resistance.

FIG. 4b A schematic cross sectional view of the channel region of a metal oxynitride transistor (400′) having a first metal oxynitride channel layer (110) and a second metal oxynitride barrier layer (120), a first gate layer (150) and a second gate layer (410′) to reduce gate series resistance, where the second gate layer (410′) has a length substantially greater than the first gate layer length, forming a T-gate structure.

FIG. 5 A schematic cross sectional diagram of the channel region of a metal oxynitride transistor (500) having a first metal oxynitride channel layer (110), a second metal oxynitride barrier layer (120). A buffer layer (510) is introduced between the substrate and the first metal oxynitride channel layer to reduce defects in the first metal oxynitride channel layer and to achieve high charge carrier mobility.

FIG. 6a A schematic cross sectional view of the channel region of a metal oxynitride transistor (600) having a first metal oxynitride channel layer (110), a second metal oxynitride barrier layer (120), a buffer layer (510). The metal oxynitride transistor (600) further comprises a carrier blocking layer (610) deposited between the buffer layer (510) and the first metal oxynitride channel layer (110) to confine free charge carriers in the first metal oxynitride channel layer (110) and to achieve high charge carrier mobility.

FIG. 6b An energy band diagram of the metal oxynitride transistor (600) taken along line C-D in FIG. 6a, showing confinement of free electrons (170E) in the first metal oxynitride channel layer (110).

FIG. 7 A schematic cross sectional diagram of a metal oxynitride transistor (700) having a first metal oxynitride channel layer (110), a second metal oxynitride barrier layer (120), a source (130), a drain (140), a first gate layer (150) and a first passivation layer (710) to passivate surface of the metal oxynitride transistor.

FIG. 8 A schematic cross sectional view of a metal oxynitride transistor (800) having a first metal oxynitride channel layer (110), a second metal oxynitride barrier layer (120), a source (130), a drain (140), a first gate layer (150). A spacer layer (810) is introduced between the first metal oxynitride channel layer (110) and the second metal oxynitride barrier layer (120) to further reduce unwanted coulomb interactions of the free electrons in the first metal oxynitride channel layer.

FIG. 9 A schematic cross sectional diagram of the channel region of a metal oxynitride transistor (900), showing a first metal oxynitride channel layer (110), a second metal oxynitride barrier layer (120), a buffer layer (510), a carrier blocking layer (610) between the buffer layer and the first metal oxynitride channel layer, a spacer layer (810) and a impurity doping layer (910) between the first metal oxynitride channel layer and the second metal oxynitride barrier layer. In this transistor, the second oxynitride barrier layer does not contain intentional doping impurities and therefore unwanted leakage between the second metal oxynitride barrier layer and first gate layer (150) is reduced and the gate breakdown voltage increased.

### DETAIL DESCRIPTION OF THE PREFERRED EMBODIMENTS

According to one embodiment of this invention, a metal oxynitride transistor (100) for forming an electronic circuit for power switching or microwave amplification, comprises a substrate (105) having a substrate thickness (105t); a first metal oxynitride channel layer (110) with a first metal oxynitride energy gap E_{g1}, a first metal oxynitride electron affinity χ₁ and a first metal oxynitride thickness (110t); a second metal oxynitride barrier layer (120) having a second metal oxynitride energy gap E_{g2}, a second metal oxynitride electron affinity and a second metal oxynitride thickness (120t); a source layer (130) with a source layer thickness (130t); a drain layer (140) with a drain layer thickness (140t) and a least a first gate layer (150) having a first gate layer length (150L) and a first gate layer thickness (150t).

In order to achieve high charge carrier mobilities, metals for forming the first metal oxynitride channel layer (110) are selected from a group including: In, Zn, Sn, Ga, Ba, La, Al, Mg and their mixtures. Some examples of the first metal oxynitride channel layer are: InO_{y}N_{1-y}, InₓSn₁₋ₓO_{y}N_{1-y}, InₓZn₁₋ₓO_{y}N_{1-y}, InₓGa₁₋ₓO_{y}N_{1-y}, InₓMg₁₋ₓO_{y}N SnₓZn₁₋ₓO_{y}N_{1-y}, SnₓBa₁₋ₓO_{y}N_{1-y}, Snₓ(Ba,La)_{1-y}O_{y}N_{1-y}, with 0≦x≦1 and 0≦y≦1. Additional metal elements such as B, Mg, Ca, Sr. Ba may be added to adjust conductivity of the films. The exact values of x and y for best performance of the present metal oxynitride transistors are determined by the material combinations and other factors. For instance, the charge carrier mobility in a metal oxynitride film is dependent on the donor density in the film. Even with the same stoichiometric composition, two films with different donor concentrations will have different charge carrier mobilities. Take InO_{y}N_{1-y} as example, the free electron mobility in the indium oxynitride with a large y value increases by a factor of about 20 to 100 as the donor concentration (whether intentional or un-intentional) in the film is decreased from a value of 5×10²⁰ cm⁻³ to 5×10¹⁷ cm⁻³.

Furthermore, charge carrier mobility for metal oxynitrides having different nitrogen contents (or 1-y values) are also different. Comparing to a room temperature charge carrier mobility value of about 100 cm²/V-sec for In₂O₃ films, room temperature charge carrier mobility for InO_{y}N_{1-y} films having similar donor concentration and crystalline quality increases to about 2,000 cm²/V-sec. For crystalline InO_{y}N_{1-y} with y<0.4, the charge carrier mobility will be more than 500 cm²N-sec. Similar performance can be implemented using InₓSn₁₋ₓO_{y}N_{1-y}, InₓZn_{1- x}O_{y}N_{1-y}, InₓGa₁₋ₓO_{y}N_{1-y}, InₓMg₁₋ₓO_{y}N_{1-y}, SnₓZn₁₋ₓO_{y}N_{1-y}, SnₓBa₁₋ₓO_{y}N_{1-y} or Snₓ(Ba,La)₁₋ₓO_{y}N_{1-y} as the first metal oxynitride channel layer, here 0≦x≦1 and 03<y≦1.

It is noted that in order to maintain high charge carrier mobilities, the donor density in the first metal oxynitride channel layer (110) should be kept low: less than 10¹⁸ cm⁻³ and more preferably less than 10¹⁷ cm⁻³. Once the values of x and y for the material of the first metal oxynitride channel layer (110) have been selected, both the first metal oxynitride energy E_{g1} and the first metal oxynitride electron affinity χ₁ are specified.

The first metal oxynitride thickness (110t) is selected to be in a range of 5 nm to 1000 nm and more preferably in a range of 10 nm to 400 nm, as long as the OFF state resistance R_{OFF} is much greater than the ON state resistance R_{ON} so that a larger than 10³ R_{OFF}/R_{ON} ratio is reached, or more preferably a larger than 10⁶ R_{OFF}/R_{ON} ratio is reached.

To provide charge carriers for conductions between the source (130) and the drain (140), donors are introduced in the second metal oxynitride barrier layer (120). Metals for the second metal oxynitride barrier layer are selected from a group including: In, Zn, Sn, Ga, Ba, La, Al, Mg and their mixtures. Examples may include: InO_{y}N_{1-y}, InₓSn₁₋ₓO_{y}N_{1-y}, InₓZn₁₋ₓO_{y}N_{1-y}, InₓGa₁₋ₓO_{y}N_{1-y}, InₓMg₁₋ₓO_{y}N_{1-y}, SnₓZn₁₋ₓO_{y}N_{1-y}, SnₓBa₁₋ₓO_{y}N_{1-y} and Snₓ(Ba,La)₁₋ₓO_{y}N_{1-y}, with 0≦x≦1 and 0≦y≦1. Additional metal elements such as B, Mg, Ca, Sr. Ba may be added to adjust the conductivity. The exact values of x and y for best performance of the present metal oxynitride transistor are determined by the material combinations. It is noted that the needs to maintain a high carrier mobility in the second metal oxynitride barrier layer (120) are not critical. And it is preferred to achieve a high donor concentration, more than 10¹⁹ cm⁻³ for a second metal oxynitride thickness (120t) of 10 nm, so that the surface donor density is more than 10¹³ cm⁻². Such donors are preferably obtained by introduction of foreign impurity atoms or by creating oxygen or nitrogen vacancies.

Once the x and y values for the second metal oxynitride barrier layer material have been selected, both the second metal oxynitride energy E_{g2} and the second metal oxynitride electron affinity χ₂ are specified. The second metal oxynitride thickness (120t) is selected to be in a range of 3 nm to 200 nm and more preferably in a range of 5 nm to 40 nm, as long as the modulation of charges in the first metal oxynitride channel layer (110) is effective with a small enough delay and the unwanted breakdown between the first gate layer (150) and the drain (140) occurs at a high enough voltage.

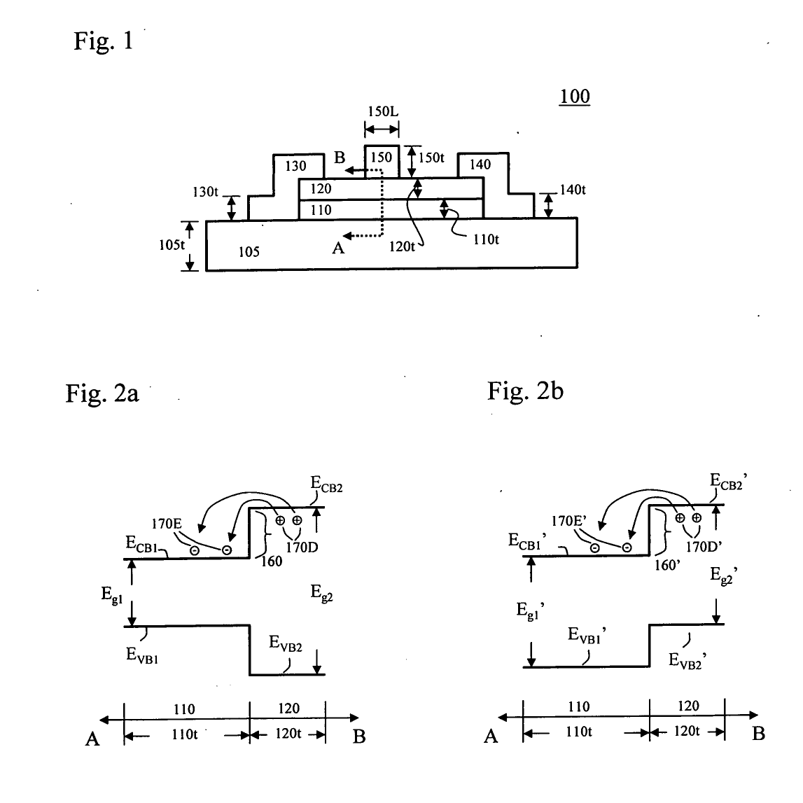

In another embodiment of the current invention, a simplified energy band diagram for the metal oxynitride transistor (100) taken along the line A-B (FIG. 1) through the first metal oxynitride channel layer (110) and second metal oxynitride barrier layer (120) is shown in FIG. 2a. In this transistor (100), the first metal oxynitride energy gap E_{g1} for the first metal oxynitride channel layer (110) is selected to be smaller than the second metal oxynitride energy gap E_{g2} of the second metal oxynitride barrier layer (120), so that there is a conduction band energy step ΔE_{C} (160) between a first metal oxynitride conduction band edge E_{CB1} and a second metal oxynitride conduction band edge E_{CB2}′: ΔE_{C}=E_{CB2}−E_{CB1}. The valence band edges are represented by E_{VB1} and E_{VB2} respectively. An electron (170E) donated by a donor (170D) in the second metal oxynitride barrier layer (120) will become a negative free charge and will drift to the first metal oxynitride channel layer (110) due to the electric field arising from the conduction band energy step ΔE_{C} (160). The ionized donor (170D) will have a positive charge which is immobile and is separated from the negative free charge (170E). Due to the separation the unwanted coulomb interactions between the ionized donor (170D) and the negative free charge (170E) is reduced so that mobility of negative free charge is high.

In the event when the first metal oxynitride energy gap E_{g1}′ for the first metal oxynitride channel layer (110) is selected to be similar to the second metal oxynitride energy gap E_{g2}′ for the second metal oxynitride barrier layer (120), then it is preferred to have the first metal oxynitride electron affinity χ₁ for the first metal oxynitride channel layer (110) to be greater than the second metal oxynitride electron affinity χ₂. Such a case is shown in a simplified energy band diagram in FIG. 2b, which is taken along line A-B in FIG. 1 through the first metal oxynitride channel layer (110) and second metal oxynitride barrier layer (120). By selecting the first metal oxynitride electron affinity χ₁ to be greater than the second metal oxynitride electron affinity χ₂, there is a conduction band energy step ΔE_{c}′ (160′) between the first metal oxynitride conduction band edge E_{CB1}′ and the second metal oxynitride conduction band edge E_{CB2}′: ΔE_{C}=E_{CB2}=E_{CB1}′=χ₁−χ₂. The valence band edges are represented by E_{VB1}′ and E_{VB2}′.

An electron (170E′) donated by a donor (170D′) introduced in the second metal oxynitride barrier layer (120) will become a negative free charge and will drift to the first metal oxynitride channel layer due to the electric field arising from the conduction band energy step ΔE_{C}′ (160′). The ionized donor (170D′) will have a positive charge which is immobile and is separated from the negative free charge. Due to the separation, the unwanted coulomb interactions between ionized donor (170D′) and the negative free charge (170E′) is reduced so that mobility of negative free charges or free electrons is high.

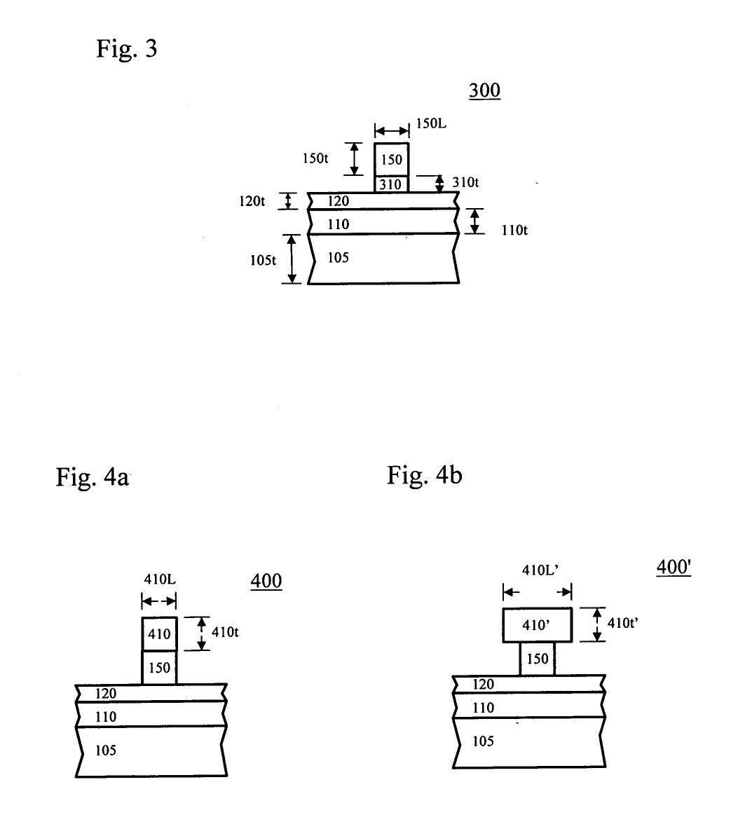

According to yet another embodiment of this invention, a metal oxynitride transistor (300, FIG. 3) for forming an electronic circuit comprises a substrate (105) with substrate thickness (105t); a first metal oxynitride channel layer (110) with a first metal oxynitride energy gap E_{g1}, a first metal oxynitride electron affinity χ₁ and a first metal oxynitride thickness (110t); a second metal oxynitride barrier layer (120) having a second metal oxynitride energy gap E_{g2}, a second metal oxynitride electron affinity χ₂ and a second metal oxynitride thickness (120t); a source layer with a source layer thickness (not shown), a drain layer with a drain layer thickness (not shown) and at least a first gate layer (150) having a first gate layer length and a first gate layer thickness (150t). The transistor (300) further comprises a gate insulating layer (310) with a gate insulating layer thickness (310t) deposited between the second metal oxynitride layer (120) and the gate layer (150), forming an MIS structure for reducing leakage currents from the first gate layer (150) and for modulating free charges in the first metal oxynitride channel layer (110). Materials of the gate insulating layer (310) may be selected from a group of silicon dioxide (SiO₂), silicon nitride (Si₃N₄), aluminum oxide (Al₂O₃), aluminum nitride (AlN), hafnium oxide (HfO₂), gallium oxide (Ga₂O₃), barium strontium titanite and their mixtures. The gate insulating layer is required to has a large breakdown voltage, a low leakage current and preferably to have a negative or low positive fixed gate insulating charges. Gate insulating layer thickness (310t) is selected according to the breakdown voltage and operating frequency requirements and is often less than 100 nm.

In order to modulate free charges in the first metal oxynitride channel layer (110) in the metal oxynitride transistor (300), a voltage applied to the first gate layer (150) should be able to vary the depletion region width under the first gate layer. Material of the first gate layer (150) is selected from a group of large work function metals including: Ni, W, Mo, Ta, Pt, Cu, Al, Au and their alloys so that a rectifying contact is formed between the first gate layer and the second metal oxynitride barrier layer (120). Therefore, it has become obvious that in forming the first gate layer (150), the first metal material to put down and to contact the surface of the second metal oxynitride barrier layer (120) should have a work function as large as possible, such as Ni, Pt, Au etc. The length of the first gate layer (150L) may be in the range from 50 nm to 3,000 nm or larger, dependent on the power handling capability requirement and the operating frequency.

For high frequency operations which simultaneously require high input power efficiency, the unwanted series resistance of the gate layer (150) in the direction pointing into the page in FIG. 1 may be too high. According to yet another embodiment of this invention, a metal oxynitride transistor (400) for forming an electronic circuit further comprises a second gate layer (410) as shown in FIG. 4a. The second gate layer (410) has a second gate layer thickness (410t) and a second gate layer length (410L) and it is directly deposited on top of the first gate layer (150). Material of the second gate layer (410) is selected from high conductivity metals including: Au, Al, Cu, Ag and their combinations, to reduce unwanted gate series resistance. Second gate layer length (410L) may be selected to be substantially the same as the first gate layer length (150L). With the addition of the second gate layer (410), unwanted series resistance of the gate layers many be reduced to facilitate fast switching.

Alternately, second gate layer length (410L′) may also be selected to be substantially larger than the first gate layer length (150L) in a metal oxynitride transistor (400′) forming a T-gate structure as shown in FIG. 4b. With the addition of the second gate layer (410′) with a large second gate layer length (410L′) and a second gate layer thickness (410t), the unwanted series resistance of the combined gate layers may be reduced further.

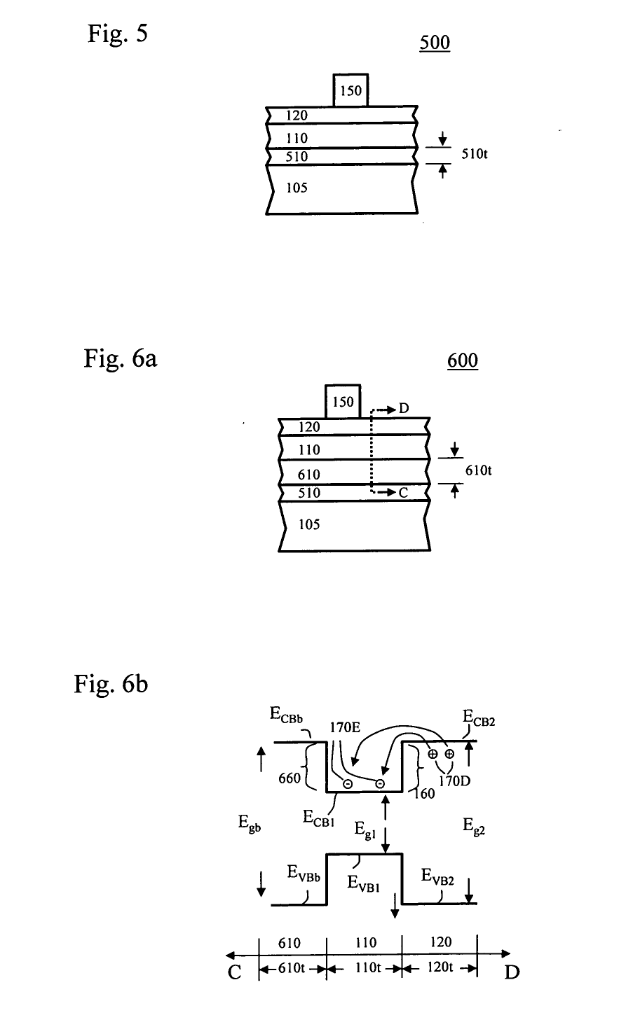

In many applications, it is preferred to have large area and low cost substrates such as glass plate, alumina plate, plastic sheets and metal sheets. In order to reduce the possible detrimental effects of the substrates on quality of the first metal oxynitride channel layer and the second oxynitride barrier layer, a buffer layer (510) having a buffer layer thickness (510t) is adopted between the substrate (105) and the first metal oxynitride channel layer (110) in metal oxynitride transistor (500) as shown in FIG. 5. This buffer layer (510) is deposited on the substrate (105) to passivate the substrate surface so that when the first metal oxynitride channel layer (110) is deposited, minimum defects will occur in the first metal oxynitride channel layer and hence a large charge carrier mobility will be achieved in the first metal oxynitride channel layer (110). The materials for the buffer layer (510) may be selected to be a high quality SiO₂ when a glass plate is used as the substrate. It may also be selected to be the same as the first metal oxynitride channel layer (110).

For applications requiring low output leakages and high frequency switching, it is required to confine free charge carriers in a well-defined first metal oxynitride channel layer. According to another embodiment of the present invention and as shown in FIG. 6a, a metal oxynitride transistor (600) further comprises a carrier blocking layer (610) with a carrier blocking layer thickness (610t) and a carrier blocking layer energy gap E_{gb} deposited between the substrate (105) (when no buffer layer is adopted) or the buffer layer (510) and the first metal oxynitride channel layer (110). The carrier blocking layer thickness (610t) is selected to be: between 20 nm and 2,000 nm to reduce unwanted defects and to confine free electrons in the first metal oxynitride channel layer (110).

A simplified energy band diagram for the metal oxynitride transistor (600) is shown in FIG. 6b, which is taken along the line C-D in FIG. 6a and through the carrier blocking layer (610), the first metal oxynitride channel layer (110) and the second metal oxynitride barrier layer (120). In FIG. 6b, the conduction band edges are represented by E_{CBb}, E_{CB1} and E_{CB2} and the valence band edges are represented by E_{VBb}, E_{VB1}and E_{VB2} for the carrier blocking layer (610), the first metal oxynitride channel layer (110) and the second metal oxynitride barrier layer (120) respectively. In this transistor (600), the first metal oxynitride energy gap E_{g1} for the first metal oxynitride channel layer (110) is selected to be smaller than the second metal oxynitride energy gap E_{g2} of the second metal oxynitride barrier layer (120), so that there is a conduction band energy step ΔE_{C} (160) between the first metal oxynitride conduction band edge E_{CB1} and the second metal oxynitride conduction band edge E_{CB2}: ΔE_{C}=E_{CB2}−E_{CB1}.

The material for the carrier blocking layer (610) should be selected to ensure a second energy step (660) between the carrier blocking layer conduction band edge E_{CBb} and the first metal oxynitride conduction band edge E_{CB1} so that free charge carriers (170E) donated by donor (170D) in the second metal oxynitride barrier layer (120) will be confined within the first metal oxynitride channel layer (110).

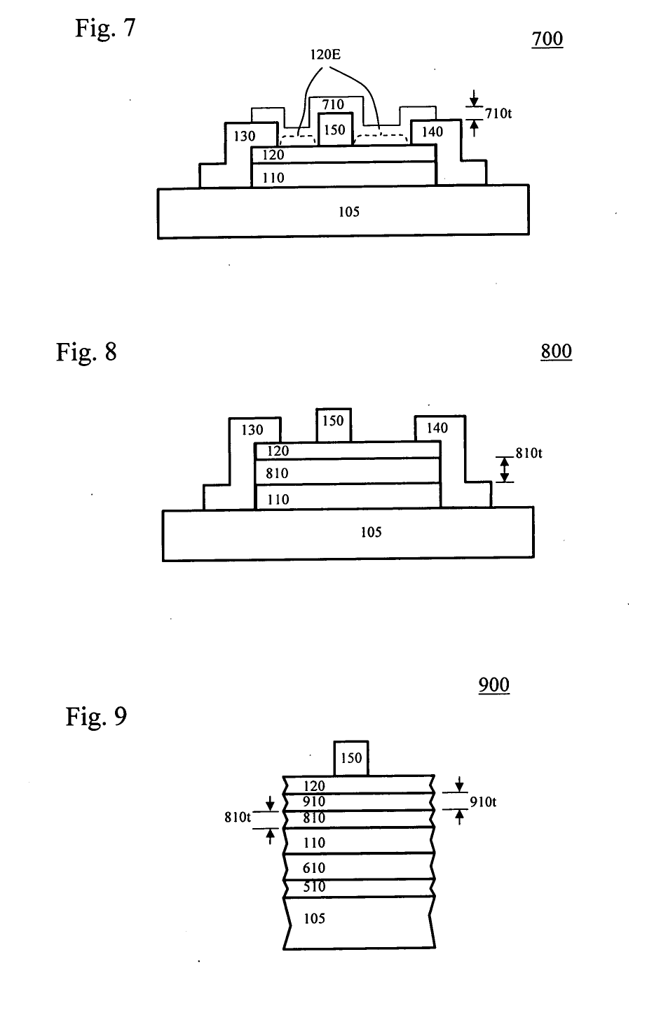

According to one embodiment of the present invention and as shown in FIG. 7, a passivation layer (710) is added in the metal oxynitride transistor (100) as shown in FIG. 1 to form a metal oxynitride transistor (700) with an improved thermal stability. This passivation layer (710) has a passivation layer thickness (710t) and covers a portion of the source layer (130), a portion of the drain layer (140), the gate layer (150) and the exposed regions (120E) of the second metal oxynitride barrier layer (120). Material of the passivation layer (710) may be selected from a group including: silicon dioxide SiO₂, silicon nitride Si₃N₄, HfO₂, and their combinations.

In order to connect the first metal oxynitride channel layer (110) to other devices in the formed electronic circuit, low resistance contacts should be achieved between the source layer (130) and the first metal oxynitride channel layer (110) and between the drain layer (140) and the first metal oxynitride channel layer (110). According to one embodiment of this invention, to ensure low resistance contacts between the first metal oxynitride channel layer (110) and the source and the drain layers (130, 140), the metals for the source layer (130) and the drain layer (140) are selected to ensure at least one of the selected metals has a low work function, such as: Ti, Ni, W, Mo, Ta, Pt, Cu, Al, Au and their alloys.

Furthermore, it is obvious for those skilled in the arts that in forming the source contact and the drain contact, the first metal material to put down and to contact the surface of the second metal oxynitride barrier layer (120) should have a work function which is close to the work function of the second metal oxynitride barrier layer (120), such as Ti or its alloys.

The metal oxynitride transistors provided in the present invention for forming an electronic circuit comprises a substrate, a first metal oxynitride channel layer (110) with a first metal oxynitride energy gap, a first metal oxynitride electron affinity and a first metal oxynitride thickness; a second metal oxynitride barrier layer having a second metal oxynitride energy gap, a second metal oxynitride electron affinity and a second metal oxynitride thickness; a source layer with a source layer thickness; a drain layer with a drain layer thickness; and at least a first gate layer having a first gate layer thickness may be adopted preferably in applications for power switching and high frequency signal amplifications.

For power switching applications such as backplane of electronic liquid crystal display or organic light emitting displays, the present metal oxynitride transistors are formed in two dimensional arrays on substrates such as: glass plate, plastic sheet, stainless steel sheets. For power switching applications such as wireless charging or microwave switching, the present metal oxynitride transistors are formed into switching circuits on substrates such as: glass plate, alumina plate, aluminum nitride plate, silicon wafer and silicon with prefabricated digital and analog microelectronic circuits for control and signal conditioning. For amplification of microwave and millimetre wave signals, the present metal oxynitride transistors are formed into amplifying circuits on substrates such as: glass plate, alumina plate, aluminum nitride plate, silicon wafer, gallium arsenide or silicon substrate with preformed digital and analog circuit.

In order to further reduce possible coulomb interactions between free carriers or free electrons migrated or drifted into the first metal oxynitride channel layer and the immobile ions of the impurity atoms in the metal oxynitride transistors, according to yet another embodiment of this invention and as shown in FIG. 8, a spacer layer (810) having a spacer layer thickness (810t) is deposited between the first metal oxynitride channel layer (110) and the second metal oxynitride barrier layer (120) in a metal oxynitride transistor (800). Material of the spacer layer (810) is preferably to be the same as that for the second metal oxynitride barrier layer (120) except with no doping impurity atoms and without significant amount of vacancies in the spacer layer. The spacer layer thickness (810t) is selected to be between 1 nm and 10 nm to reduce further unwanted coulomb interactions of free electrons in the first metal oxynitride channel layer (110) and to enhance the charge carrier mobility.

When a Schottky contact is formed between a metal and a metal oxynitride layer with high impurity concentration, the reverse direction leakage current may be large and a reduced breakdown voltage may be resulted. In order overcome the above difficulties, according to still another embodiment of this invention and as shown in FIG. 9, a metal oxynitride transistor (900) for forming an electronic circuit, further comprises an impurity doping layer (910) with an impurity doping layer thickness (910t) deposited between the first metal oxynitride channel layer (110) and second oxynitride barrier layer (120). In transistor (900), the free electrons for the conduction in the first metal oxynitride channel layer (110) are supplied by the impurities contained in the impurity doping layer (910). With the impurity doping layer (910) in place, no intentional impurity doping is introduced in the second metal oxynitride barrier layer (120) so that the immobile ion density is low in this barrier layer (120), therefore, unwanted leakage current in the Schottky contact made with the first gate layer (150) will be reduced and the gate breakdown voltage will be increased.

In order to reduce the unwanted coulomb interactions of free electrons with immobile ions of impurity atoms, it is also preferred to adopt a spacer layer (810) having a spacer layer thickness (810t) in the metal oxynitride transistor (900). In this manner, the mobility of free charges or free electrons will be high. In the metal oxynitride transistor (900), a buffer layer (510) and a carrier blocking layer (610) are also present between the substrate (105) and the first metal oxynitride channel layer (110) to passivate the substrate surface, to reduce unwanted defects and to confine free carriers in the first metal oxynitride channel layer to achieve higher charge carrier mobilities.

1. A metal oxynitride transistor for forming an electronic circuit, comprises:
a substrate;
a first metal oxynitride channel layer with a first metal oxynitride energy band gap, a first metal oxynitride electron affinity, a first metal oxynitride donor density and a first metal oxynitride channel layer thickness;
a second metal oxynitride bather layer having a second metal oxynitride energy band gap, a second metal oxynitride electron affinity, a second metal oxynitride donor density and a second metal oxynitride barrier layer thickness to provide electrons, said second metal oxynitride donor density is higher than said first metal oxynitride donor density;
a source layer with a source layer thickness;
a drain layer with a drain layer thickness; and
at least a first gate layer having a first gate layer length and a first gate layer thickness, wherein said first metal oxynitride energy band gap, said first metal oxynitride electron affinity, said second metal oxynitride energy band gap and said second metal oxynitride electron affinity are selected to form an conduction energy band step between said second metal oxynitride bather layer and said first metal oxynitride channel layer so that free electrons donated in said second metal oxynitride barrier layer will be separated from ionized donors and move into said first metal oxynitride channel layer to achieve high electron mobility for conduction between said source layer and said drain layer.

2. The metal oxynitride transistor for forming the electronic circuit as defined in claim 1, wherein metals for forming said first metal oxynitride channel layer are selected from a group including: In, Zn, Sn, Ga, Ba, La, B, Al, Mg, Ca, Sr, Ba and their mixtures.

3. The metal oxynitride transistor for forming the electronic circuit as defined in claim 1, wherein metals for forming said second metal oxynitride bather layer are selected from a group including: In, Zn, Sn, Ga, Ba, La, B, Al, Mg, Ca, Sr, Ba and their mixtures.

4. The metal oxynitride transistor for forming the electronic circuit as defined in claim 1, wherein doping impurity atoms are introduced in said second metal oxynitride bather layer to donate electrons and no intentional doping impurity atoms are introduced in said first metal oxynitride channel layer, said electrons donated by said doping impurity atoms in said second metal oxynitride barrier layer drift or migrate to said first metal oxynitride channel layer.

5. The metal oxynitride transistor for forming the electronic circuit as defined in claim 1, wherein said first metal oxynitride energy band gap is smaller than said second metal oxynitride energy band gap for forming a conduction energy band step between said first metal oxynitride channel layer and said second metal oxynitride barrier layer to facilitate separation of free charges from immobile ionized donors in said second metal oxynitride barrier layer and to increase mobility of said free charges.

6. The metal oxynitride transistor for forming the electronic circuit as defined in claim 1, wherein said first metal oxynitride energy band gap is similar to said second metal oxynitride energy band gap and said first metal oxynitride electron affinity is greater than said second metal oxynitride electron affinity for forming a conduction energy band step between said first metal oxynitride channel layer and said second metal oxynitride bather layer to facilitate charge separation and to increase mobility.

7. The metal oxynitride transistor for forming the electronic circuit as defined in claim 1, wherein said first metal oxynitride channel layer thickness is selected to be in a range of 5 nm to 1000 nm and more preferably in a range of 10 nm to 400 nm.

8. The metal oxynitride transistor for forming the electronic circuit as defined in claim 1, wherein said second metal oxynitride bather layer thickness is selected to be in a range of 3 nm to 200 nm and more preferably in a range of 5 nm to 40 nm.

9. The metal oxynitride transistor for forming the electronic circuit as defined in claim 1, further comprising a gate insulating layer having a gate insulating layer thickness deposited between said second metal oxynitride layer and said first gate layer, forming an MIS structure to reduce leakage currents from said first gate layer and for modulating charges in said first metal oxynitride layer, wherein materials of said gate insulating layer may be selected from a group including silicon dioxide, silicon nitride, aluminum oxide, aluminum nitride, hafnium oxide, gallium oxide, barium strontium titanite and their mixtures.

10. The metal oxynitride transistor for forming the electronic circuit as defined in claim 1, wherein material of said first gate layer is selected from a group of large work function metals including: Ni, W, Mo, Ta, Pt, Cu, Al, Au and their alloys to form a rectifying contact between said first gate layer and said second metal oxynitride bather layer.

11. The metal oxynitride transistor for forming the electronic circuit as defined in claim 1, further comprising a second gate layer having a second gate length and a second gate layer thickness deposited on said first gate layer, material of said second gate layer is selected from a high conductivity materials including:
Au, Al, Cu, Ag and their combinations to reduce unwanted series resistance of said first gate layer and said second gate layer.

12. The metal oxynitride transistor for forming the electronic circuit as defined in claim 1, further comprising a buffer layer having a buffer layer thickness deposited on said substrate to reduce unwanted defect density in said first metal oxynitride channel layer.

13. The metal oxynitride transistor for forming the electronic circuit as defined in claim 1, further comprising a carrier blocking layer having a carrier blocking layer energy band gap and a carrier blocking layer thickness situated between said substrate and said first metal oxynitride channel layer to reduce defects and to confine free electrons in said first metal oxynitride channel layer, said carrier blocking layer thickness is selected to be in a range of 20 nm˜2,000 nm, wherein materials of said carrier blocking layer are selected so that an energy step is formed between conduction band edges of said carrier blocking layer and said first metal oxynitride channel layer.

14. The metal oxynitride transistor for forming the electronic circuit as defined in claim 1, further comprising a passivation layer having a passivation layer thickness covering a portion of said source layer and a portion of said drain layer, said first gate layer and exposed regions of said second metal oxynitride bather layer, wherein materials of said passivation layer are selected from a group including: silicon dioxide, silicon nitride, hafnium oxide and their combinations.

15. The metal oxynitride transistor for forming the electronic circuit as defined in claim 1, wherein materials of said source and said drain are selected to form a non-rectifying contact with low resistance between said source and drain and said first metal oxynitride channel layer.

16. The metal oxynitride transistor for forming the electronic circuit as defined in claim 1, wherein said substrate is selected from group of glass plates, plastic sheets, alumina plates, aluminum nitride plates, stainless steel sheets, silicon wafer, Si and GaAs substrates with prefabricated digital and analog microelectronic circuits.

17. The metal oxynitride transistor for forming the electronic circuit as defined in claim 1, further comprising a spacer layer having a spacer layer thickness situated between said first metal oxynitride channel layer and said second metal oxynitride barrier layer to reduce unwanted coulomb interactions of free electrons in said first metal oxynitride channel layer, said spacer layer thickness is selected to be in a range of: 1 nm˜10 nm, material of said spacer layer may be preferably selected to be the same as that of said second metal oxynitride bather layer and no intentional doping is introduced in said spacer layer.

18. The metal oxynitride transistor for forming the electronic circuit as defined in claim 1, further comprises a impurity doping layer with an impurity doping layer thickness deposited between said first metal oxynitride channel layer and said second metal oxynitride barrier layer to supply charge carriers for conduction in said first metal oxynitride channel layer, whereas no intentional impurity doping is introduced in said second metal oxynitride bather layer to reduce unwanted gate leakage and increase gate breakdown voltage.
